(19) United States
(12) Patent Application Publication
(10) Pub. No.: US 2026/0197985 A1
(43) Pub. Date: Jul. 9, 2026

(54) SEMICONDUCTOR DEVICE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Feng-Min LEE, Hsinchu City (TW); Cheng-Lin SUNG, Hsinchu County (TW)

(21) Appl. No.: 19/014,553

(22) Filed: Jan. 9, 2025

(51) Int. Cl. H10B 12/00

(52) U.S. Cl. CPC H10B 12/00

(57) ABSTRACT

A semiconductor device is provided. The semiconductor device includes a bottom plate and at least one stack stacked on the bottom plate along a first direction, wherein the at least one stack includes a first stack, and the first stack includes a plurality of insulating layers and a plurality of conductive layers, an insulating pillar, and a conductive connection structure, a dielectric layer and a channel layer. The insulating layers and conductive layers are alternately stacked on the bottom plate along the first direction. The insulating pillar extends along the first direction and penetrates the insulating layers and the conductive layers. The conductive connection structure penetrates the insulating layers and the conductive layers and surrounds the insulating pillar. A dielectric layer surrounds the conductive connection structure. The channel layer surrounds the dielectric layer and is electrically connected to the conductive connection structure.

### BACKGROUND OF THE INVENTION

### Field of the Invention

The invention relates in general to a semiconductor device and a method for manufacturing the same, and more particularly to a memory device and a method for manufacturing the same.

### Description of the Related Art

Dynamic random access memories (DRAMs) are a common type of semiconductor memory. The structure of traditional DRAM is quite simple. Each bit of data requires a transistor (1T) and a capacitor (1C) to process, that is, 1T1C DRAM. However, with the increasing applications, the size limitation of 1T1C DRAM is no longer sufficient. Therefore, in order to provide memory devices with higher storage capacity, the structure of traditional DRAM needs to be further improved.

### SUMMARY OF THE INVENTION

The present invention is directed to the improvement of a dynamic random access memory, especially the formation of a three-dimensional dynamic random access memory to improve size limitations.

According to some embodiments, the present invention provides a semiconductor device. The semiconductor device includes a bottom plate and at least one stack. The at least one stack is stacked on the bottom plate along a first direction, wherein the at least one stack includes a first stack, and the first stack includes a plurality of insulating layers and a plurality of conductive layers, an insulating pillar, a conductive connection structure, a dielectric layer and a channel layer. The insulating layers and the conductive layers are alternately stacked on the bottom plate along the first direction. The insulating pillar extends along the first direction and penetrates the insulating layers and the conductive layers. The conductive connection structure penetrates the insulating layers and the conductive layers and surrounds the insulating pillar. A dielectric layer surrounds the conductive connection structure. The channel layer surrounds the dielectric layer and is electrically connected to the conductive connection structure.

According to some embodiments, the present invention provides a method for manufacturing a semiconductor device. The method of manufacturing a semiconductor device includes providing a bottom plate and forming at least one stack stacked on the bottom plate along a first direction. The at least one stack is stacked on the bottom plate along a first direction, wherein the at least one stack includes a first stack, and the first stack includes a plurality of insulating layers and a plurality of conductive layers, an insulating pillar, a conductive connection structure, a dielectric layer and a channel layer. The insulating layers and the conductive layers are alternately stacked on the bottom plate along the first direction. The insulating pillar extends along the first direction and penetrates the insulating layers and the conductive layers. The conductive connection structure penetrates the insulating layers and the conductive layers and surrounds the insulating pillar. A dielectric layer surrounds the conductive connection structure. The channel layer surrounds the dielectric layer and is electrically connected to the conductive connection structure.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows a cross-sectional view of a semiconductor device according to an embodiment of the present invention.

FIG. 1B shows a three-dimensional (3D) view of the semiconductor device of FIG. 1A.

FIG. 1C shows a partial top view of the semiconductor device of FIG. 1A.

FIG. 1D shows a 3D view of a semiconductor device according to another embodiment of the present invention.

FIGS. 2A to 2J shows a flowchart of a method for manufacturing the semiconductor device as shown in FIGS. 1A and 1B.

### DETAILED DESCRIPTION OF THE INVENTION

Various embodiments will be described in more detail below with reference to the accompanying drawings. The narrative content and diagrams are provided for illustration only and are not intended to be limiting. For clarity, some elements and/or symbols may be omitted in some drawings. In addition, elements in the drawings may not be drawn to actual scale. It is contemplated that elements and features in one embodiment can be advantageously incorporated into another embodiment without further description.

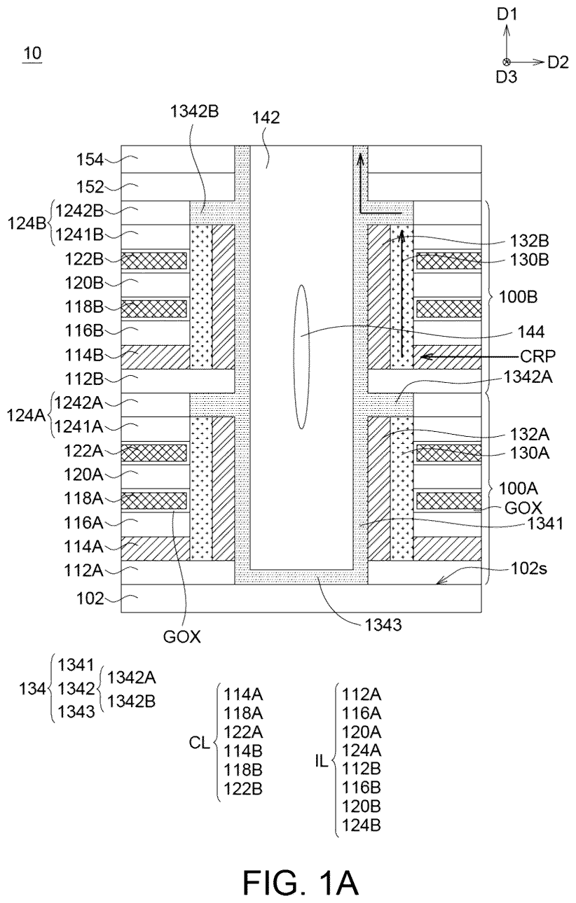

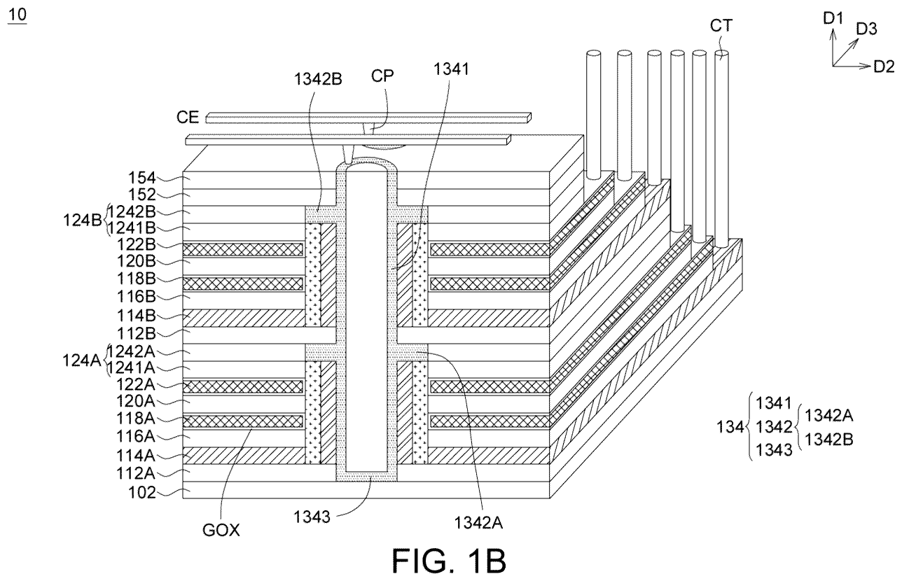

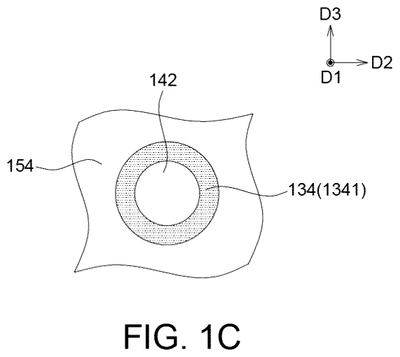

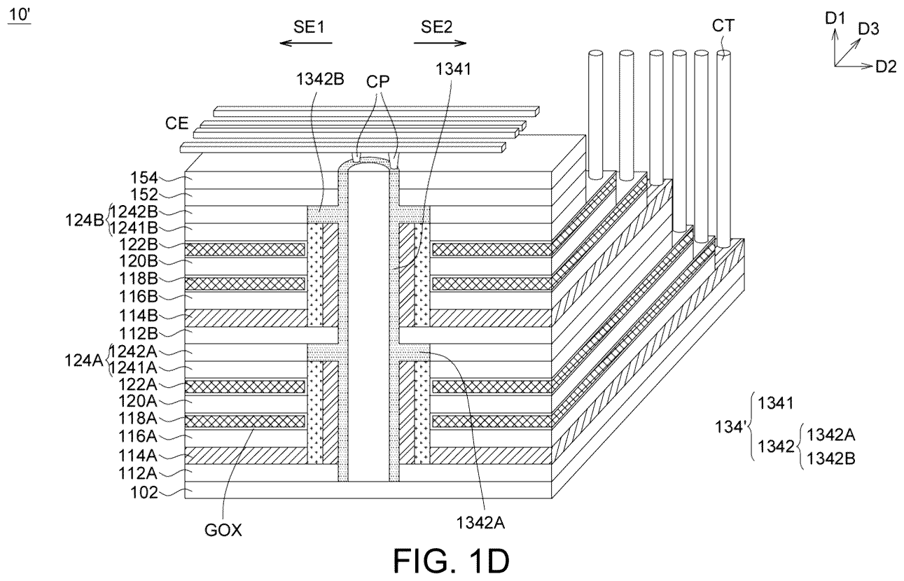

FIG. 1A shows a cross-sectional view of a semiconductor device 10 according to an embodiment of the present invention. FIG. 1B shows a 3D view of the semiconductor device 10 of FIG. 1A. FIG. 1C shows a partial top view of the semiconductor device 10 of FIG. 1A, for example, a partial top view corresponding to a conductive connection structure 134.

Please refer to FIGS. 1A-1B simultaneously. The present invention provides a semiconductor device 10. The semiconductor device 10 includes a bottom plate 102 and at least one stack stacked on the bottom plate 102 along a first direction D1. In the present embodiment, the amount of at least one stack is two, that is, the first stack 100A and the second stack 100B. The second stack 100B is stacked on the first stack 100A. However, the invention is not limited thereto. The amount of the at least one stack can be 1, 3 or more than 3. The first direction D1 is, for example, parallel to a normal direction of an upper surface 102s of the bottom plate 102, but the invention is not limited thereto.

The first stack 100A and the second stack 100B are sequentially stacked on the upper surface 102s of the bottom plate 102 along the first direction D1. The first stack 100A includes a plurality of insulating layers IL and a plurality of conductive layers CL alternately stacked on the upper surface 102s of the bottom plate 102 along the first direction D1. For example, the insulating layers IL includes a first insulating layer 112A, a second insulating layer 116A, a third insulating layer 120A, and a fourth insulating layer 124A; the conductive layer CL includes a first conductive layer 114A, a second conductive layer 118A, and a third conductive layer 122A. In other words, the first insulating layer 112A, the first conductive layer 114A, the second insulating layer 116A, the second conductive layer 118A, the third insulating layer 120A, the third conductive layer 122A and the fourth insulating layer 124A are sequentially stacked on the upper surface 102s of the bottom plate 102 along the first direction D1. The fourth insulating layer 124A is, for example, a double-layer structure and may include a first insulating portion 1241A and a second insulating portion 1242A. The second insulating portion 1242A is stacked on the first insulating portion 1241A.

According to some embodiments, the material of the insulating layers IL may include an insulating material, such as an oxide, a nitride, or other suitable insulating materials. According to an embodiment, the material of the first insulating layer 112A, the second insulating layer 116A, the third insulating layer 120A and the fourth insulating layer 124A includes oxide. For example, the first insulating layer 112A is hafnium oxide (HfO_{X}) or aluminum oxide (AlO_{X}). The material of the second insulating layer 116A, the third insulating layer 120A and the first insulating portion 1241A in the fourth insulating layer 124A may include low-density oxide, such as low-density silicon oxide. The material of the second insulating portion 1242A in the fourth insulating layer 124A may include high-density oxide, such as high-density silicon oxide or tetraethoxysilane (TEOS) oxide. The porosity of the low-density oxide is higher than the porosity of the high-density oxide. Compared with low-density silicon oxide, high-density silicon oxide has a denser structure, usually has fewer impurities, and has a higher mass per unit volume. Because the atoms of high-density silicon oxide are packed more closely, it can have better mechanical and electrical properties. Relatively, compared with the high-density silicon oxide, the low-density silicon oxide usually has a more porous structure, a lower mass per unit volume, and usually contains more impurities or voids. The lower density of low-density silicon oxide may be due to the deposition process, which may not fully compact the material, resulting in higher porosity. The etch rate (dry or wet etch) of the lower density oxide is much faster than that of the higher density oxide.

According to some embodiments, the material of the conductive layers CL may include a conductive material, such as polycrystalline silicon, metal, alloy or other suitable conductive materials. The material of the first conductive layer 114A may include polysilicon, such as N-type semiconductor heavily doped polysilicon; the materials of the second conductive layer 118A and the third conductive layer 122A may include titanium nitride (TiN) and tungsten (W).

According to some embodiments, the first stack 100A of the semiconductor device 10 may further include a channel layer 130A, a dielectric layer 132A, a conductive connection structure 134, and an insulating pillar 142. The channel layer 130A, the dielectric layer 132A, the conductive connection structure 134 and the insulating pillar 142 extend along the first direction D1 and penetrate the conductive layers CL and the insulating layers IL in the first stack 100A. For example, in the second direction D2 and the third direction D3, the channel layer 130A, the dielectric layer 132A, the conductive connection structure 134 and the insulating pillar 142 may overlap the first conductive layer 114A, the second insulating layer 116A, the second conductive layer 118A, the third insulating layer 120A, the third conductive layer 122A, and the first insulating portion 1241A in the fourth insulating layer 124A. The first direction D1, the second direction D2 and the third direction D3 can be perpendicular to each other, but the present invention is not limited thereto. The conductive connection structure 134 surrounds the insulating pillar 142, the dielectric layer 132A surrounds the conductive connection structure 134 and the insulating pillar 142, the channel layer 130A surrounds the dielectric layer 132A, the conductive connection structure 134 and the insulating pillar 142, and the conductive layers CL (such as the first conductive layer 114A, the second conductive layer 118A and the third conductive layer 122A) surround the channel layer 130A, the dielectric layer 132A, the conductive connection structure 134 and the insulating pillar 142. The dielectric layer 132A is disposed between the channel layer 130A and the first connection portion 1341 of the conductive connection structure 134 (detailed below). The channel layer 130A is electrically connected to the conductive connection structure 134. The conductive layers CL (e.g., the first conductive layer 114A, the second conductive layer 118A, and the third conductive layer 122A) are in electrical contact with the channel layer 134. In some embodiments, the second conductive layers 118A and 118B and third conductive layers 122A and 122B are surrounded by gate dielectric layers GOX, respectively. The material of the gate dielectric layers GOX may include an oxide material, for example Aluminum Oxide (AlO_{X}), Hafnium Oxide (HfO_{X}), Zirconium Oxide (ZrO_{X}) or other suitable material.

The channel layer 130A penetrates at least a portion of the conductive layers CL and the insulating layers IL of the first stack 100A along the first direction D1. That is, the channel layer 130A penetrates the first conductive layer 114A, the second insulating layer 116A, the second conductive layer 118A, the third insulating layer 120A, the third conductive layer 122A and the first insulating portion 1241A of the fourth insulating layer 124A along the first direction D1. According to an embodiment, the material of the channel layer 130A may include polysilicon.

The dielectric layer 132A penetrates at least a portion of the conductive layers CL and the insulating layers IL of the first stack 100A along the first direction D1. That is, the channel layer 130A penetrates the first conductive layer 114A, the second insulating layer 116A, the second conductive layer 118A, the third insulating layer 120A, the third conductive layer 122A and the first insulating portion 1241A of the fourth insulating layer 124A along the first direction D1. According to an embodiment, the material of the dielectric layer 132A may include silicon nitride.

The conductive connection structure 134 penetrates, for example, the entire conductive layers CL and insulating layers IL of the first stack 100A along the first direction D1. In the present embodiment, the conductive connection structure 134 includes a first connection portion 1341, a second connection portion 1342A and a third connection portion 1343, but the present invention is not limited thereto. The second connection portion 1342A and the third connection portion 1343 are connected to the first connection portion 1341. In the cross-sectional view shown in FIG. 1A, the first connection portion 1341 extends along the first direction D1 and penetrates the first insulating layer 112A, the first conductive layer 114A, the second insulating layer 116A, the second conductive layer 118A, the third insulating layer 120A, the third conductive layer 122A and the fourth insulating layer 124A. In the cross-sectional view shown in FIG. 1A, the second connection portion 1342A extends along the second direction D2, is disposed on the dielectric layer 132A and the channel layer 130A, and is in electrical contact with the channel layer 130A. The second connection portion 1342A surrounds the first connection portion 1341, overlaps the dielectric layer 132A and the channel layer 132A in the first direction D1, and overlaps the second insulating portion 1242A of the fourth insulating layer 124A in the second direction D2. In other words, the distance in the first direction D1 between the second insulating portion 1242A and the upper surface 102s of the bottom plate 102 may be equal to the distance in the first direction D1 between the second connection portion 1342A and the upper surface 102s of the bottom plate 102. In the cross-sectional view shown in FIG. 1A, the third connection portion 1343 extends along the second direction, for example, is connected to the bottom of the first connection portion 1341 and contacts the bottom plate 102. The channel layer 130A is further away from the first connection portion 1341 than the dielectric layer 132A. The material of the conductive connection structure 134 may include conductive materials, such as metal or other suitable conductive materials.

In one embodiment, the insulating pillar 142 extends along the first direction D1 and penetrates the entire insulating layers IL and conductive layers CL of the first stack 100A. The insulating pillar 142 may include an air gap 144. The material of the insulating pillar 142 may include an insulating material such as an oxide or other suitable insulating material.

In an embodiment, the first stack 100A and the second stack 100B may have identical or similar structure. The second stack 100B is stacked on the first stack 100A along the first direction D1. That is, the second stack 100B may include a first insulating layer 112B, a first conductive layer 114B, a second insulating layer 116B, a second conductive layer 118B, a third insulating layer 120B, the third conductive layer 122B and the fourth insulating layer 124B sequentially stacked on the first stack 100A along the first direction D1. The fourth insulating layer 124B may include a first insulating portion 1241B and a second insulating portion 1242B. The materials and structures of the first insulating layer 112B, the first conductive layer 114B, the second insulating layer 116B, the second conductive layer 118B, the third insulating layer 120B, the third conductive layer 122B and the first insulating portion 1241B and the second insulating portion 1242B of the fourth insulating layer 124B are the same or similar to the materials and structures of the first insulating layer 112A, the first conductive layer 114A, the second insulating layer 116A, the second conductive layer 118A, the third insulating layer 120A, the third conductive layer 122A and the first insulating portion 1241A and the second insulating portion 1242A of the fourth insulating layer 124A. The repeated parts of will not be described in detail.

The second stack 100B may further include a channel layer 130B and a dielectric layer 132B. The materials and structures of the channel layer 130B and the dielectric layer 132B are also the same or similar to the materials and structures of the channel layer 130A and the dielectric layer 132A, respectively. The conductive connection structure 134 and the insulating pillar 142 extend further through the insulating layers IL and the conductive layers CL of the second stack 100B along the first direction D1. Moreover, the conductive connection structure 134 may further include another second connection portion 1342B. The material and structure of the second connection portion 1342B are also the same or similar to the material and structure of the second connection portion 1342A.

The semiconductor device 10 may further include a first covering layer 152 and a second covering layer 154. The first covering layer 152 and the second covering layer 154 sequentially cover the second stack 100B along the first direction D1. The conductive connection structure 134 and the insulating pillar 142 extend further through the first covering layer 152 and the second covering layer 154 along the first direction D1. The materials of the first covering layer 152 and the second covering layer 154 may include oxide or other suitable insulating materials.

In a top view (as shown in FIG. 1C), the conductive connection structure 134 has a ring-shaped structure, and may have a circular profile, an elliptical profile, or other suitable shape of profile.

As shown in FIG. 1B, the semiconductor device 10 may further include a plurality of plugs CP, a plurality of contact structures CT and a plurality of conductive lines CE. The plugs CP are in electrical contact with the conductive connection structures 134, and the conductive lines CE are in electrical contact with the corresponding plugs CP respectively. The contact structures CT are in electrical contact with the corresponding conductive layers CL respectively, for example, they are in electrical contact with the first conductive layer 114A, the second conductive layer 118A, the third conductive layer 122A, the first conductive layer 114B, and the second conductive layer 118B and third conductive layer 122B respectively.

According to some embodiments, the first conductive layers 114A and 114B can serve as a source line, respectively; the second conductive layer 118A, the third conductive layer 122A, the second conductive layer 118B and the third conductive layer 122B can serve as a word line, respectively; the conductive connection structure 134 can serve as a bit line or be electrically connected to a bit line.

In the first stack 100A, intersection positions of the channel layer 130A, the second conductive layer 118A and the third conductive layer 122A form 2 serial transistors (2T); in the second stack 100B, intersection positions of the channel layer 130B, the second conductive layer 118B and the third conductive layer 122B form 2 serial transistors. Therefore, the semiconductor device 10 of the present embodiment can form a three-dimensional bi-transistor capacitorless dynamic random access memory (3D 2T capacitorless DRAM). The present invention is not limited thereto. In other embodiments, the amount of the conductive layers and the amount of the stacks can be greater. Since the semiconductor device of the present invention has a stacking direction along the first direction D1 (for example, vertically stacked), it is a very easy stacking method and is beneficial to the development of miniaturized components. Therefore, compared with the traditional 1T 1C DRAM, the semiconductor device of the present invention can solve the scaling issue and provide a memory device with a higher storage capacity.

Referring to FIG. 1A, the second conductive layer 118A is the first gate, the third conductive layer 122A is the second gate, and the channel layer 130A is the channel of bottom 2T DRAM device; the second conductive layer 118B is the first gate, the third conductive layer 122B is the second gate, and the channel layer 130B is the channel of top 2T DRAM device.

As shown in the current path CRP in FIG. 1A, the current can flow from the first conductive layer 114B into the channel layer 130B, and then flow through the second connection portion 1342B and the first connection portion 1341 of the conductive connection structure 134. Similarly, the current can flow from the first conductive layer 114A into the channel layer 130A, and then flow through the second connection portion 1342A and the first connection portion 1341 of the conductive connection structure 134.

According to some embodiments, the thicknesses of the second conductive layer 118A (or 118B) and the third conductive layer 122A (or 122B) in the first direction D1 may be the same or different. The second conductive layers 118A and 118B and the third conductive layers 122A and 122B can respectively be applied with different voltages and have different functions. For example, one of the second conductive layer 118A (or 118B) and the third conductive layer 122A (or 122B) serves as a control gate, and the other serves as an auxiliary gate to avoid leakage current.

According to some embodiments, the second conductive layer 118A (or 118B) and the third conductive layer 122A (or 122B) may have a high-k metal gate structure, so the semiconductor device 10 may have excellent operating performance.

FIG. 1D shows a perspective view of a semiconductor device 10′ according to another embodiment of the present invention. The difference between the semiconductor device 10′ and the semiconductor device 10 is that the conductive connection structure 134′ includes the first connection portion 1341 and the second connection portions 1342A and 1342B, but does not include the third connection portion 1343, and the amount of the plugs CP and the amount of the conductive lines CE are different, and other identical or similar parts will not be described in detail.

Please refer to FIG. 1D. The conductive connection structure 134′ is electrically connected to the plugs CP located on opposite sides (the first side SE1 and the second side SE2), so the voltages can be applied to the conductive connection structure 134′ through different conductive lines CL and plugs CP.

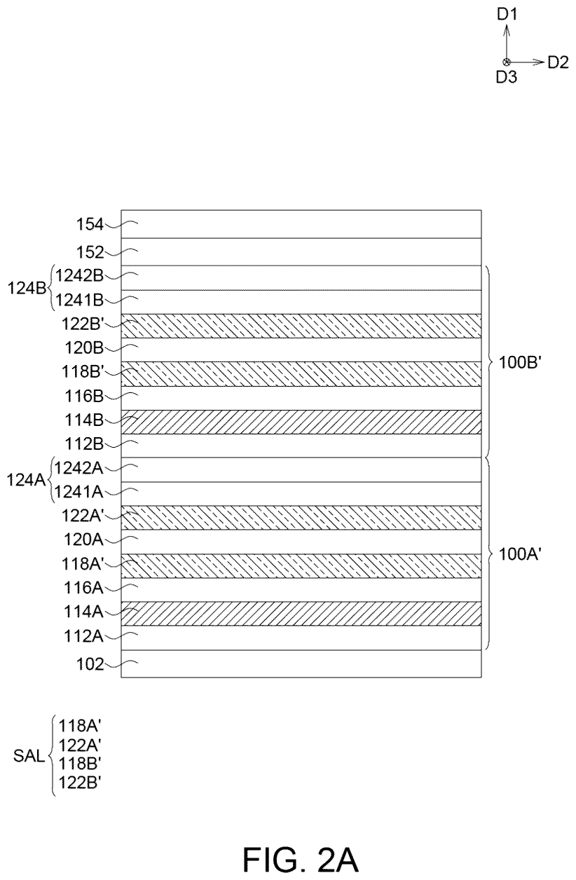

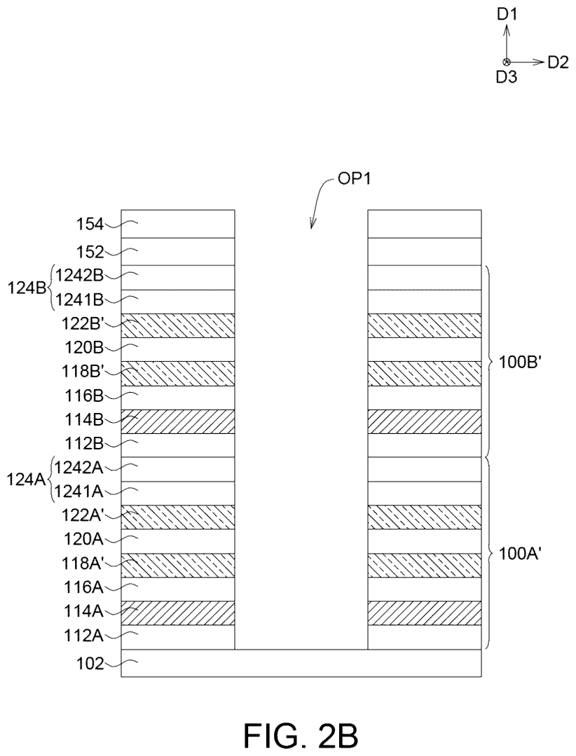

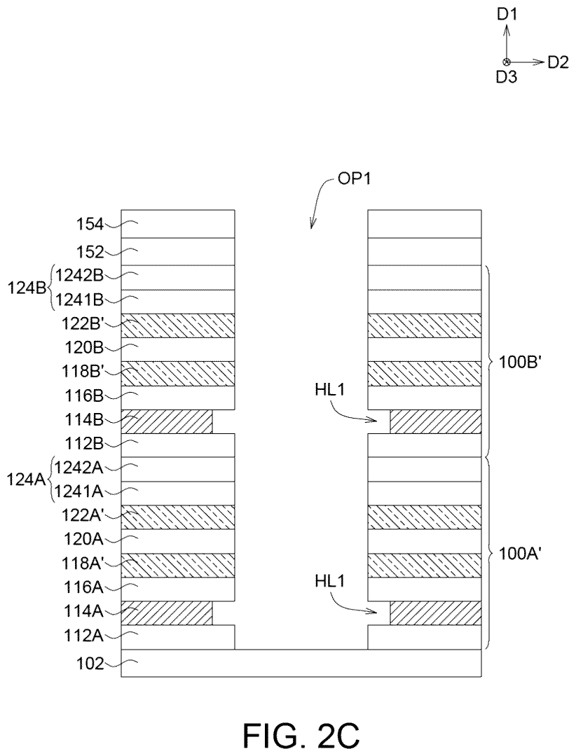

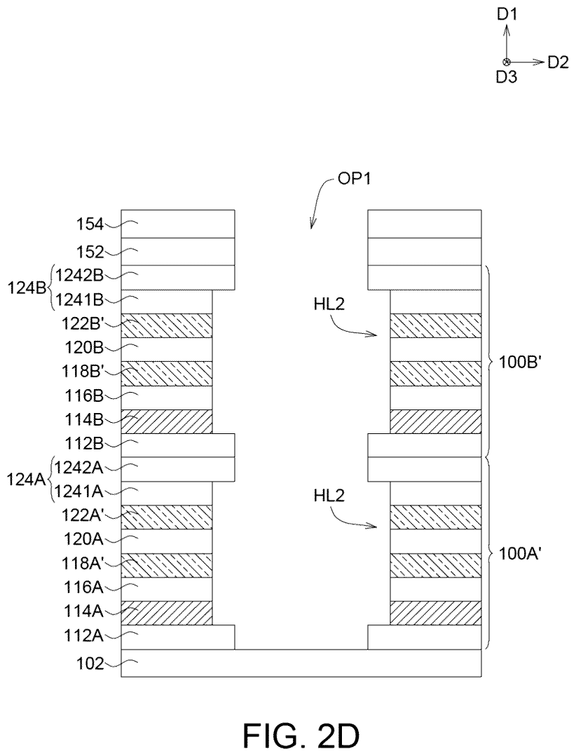

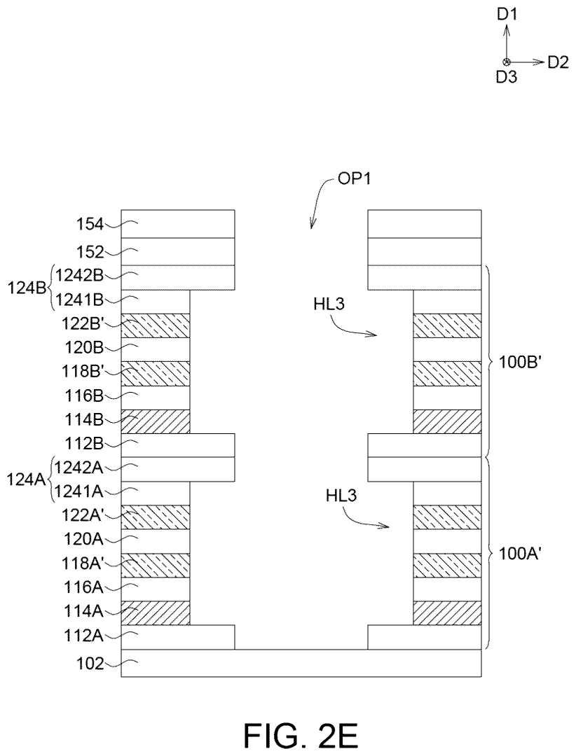

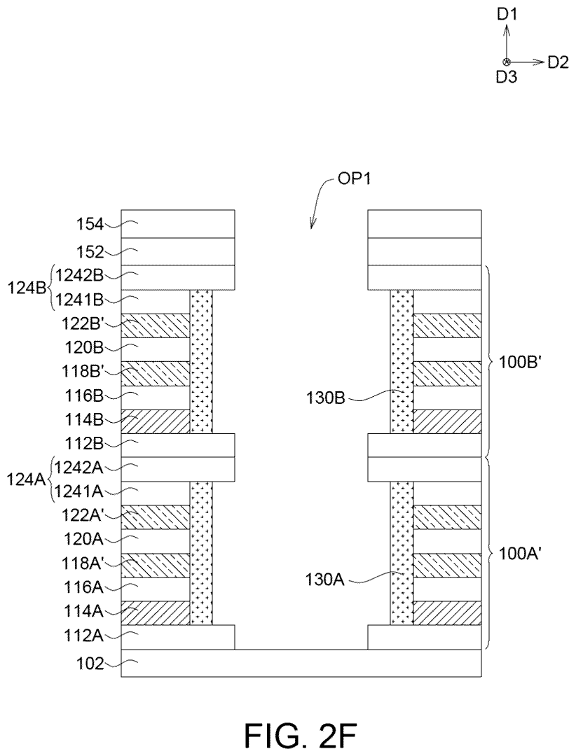

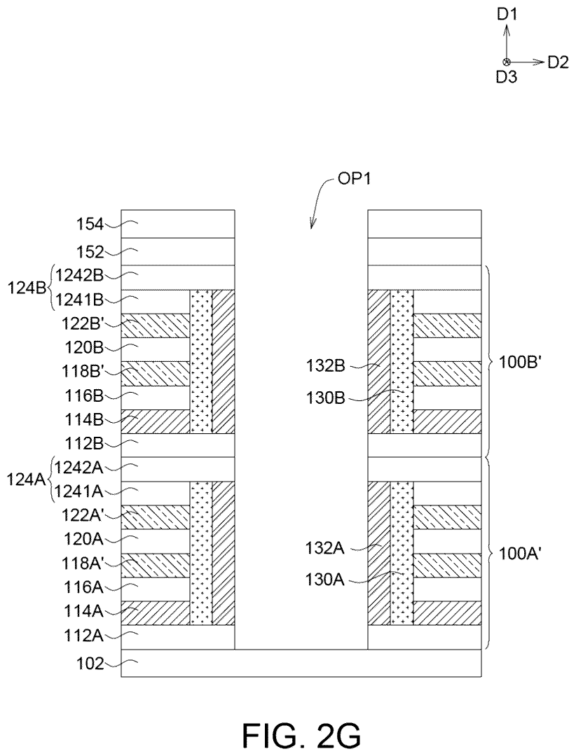

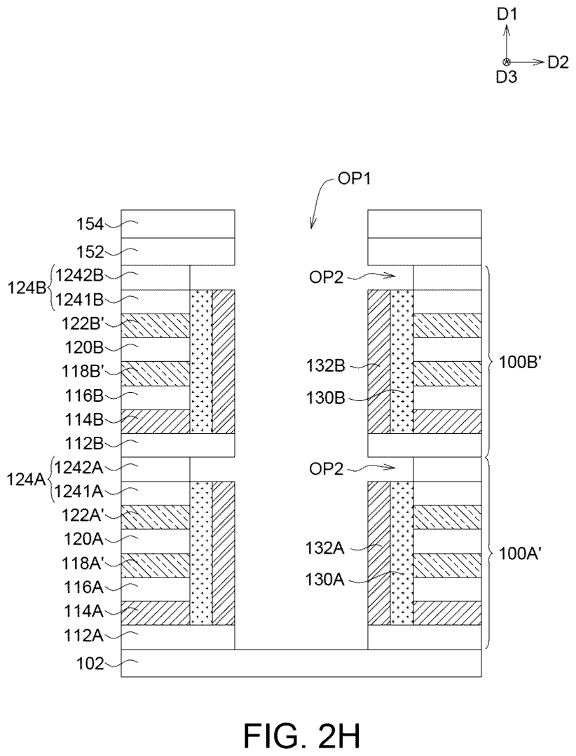

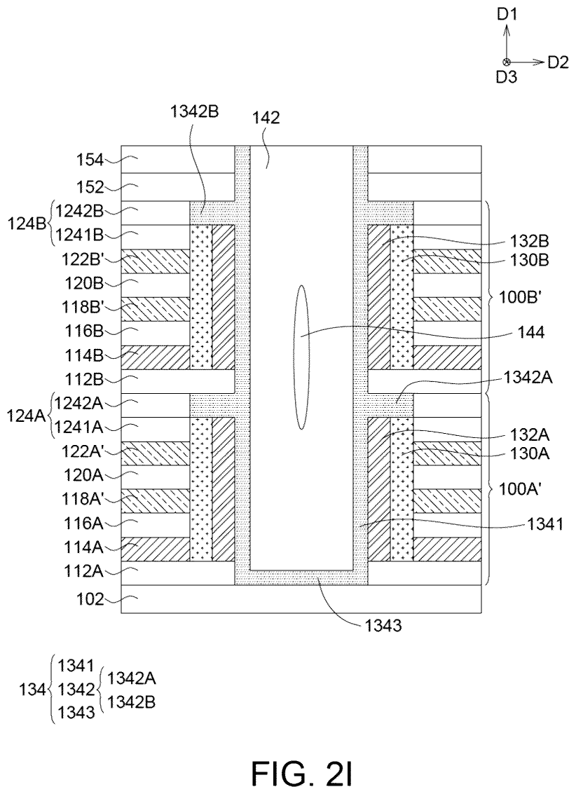

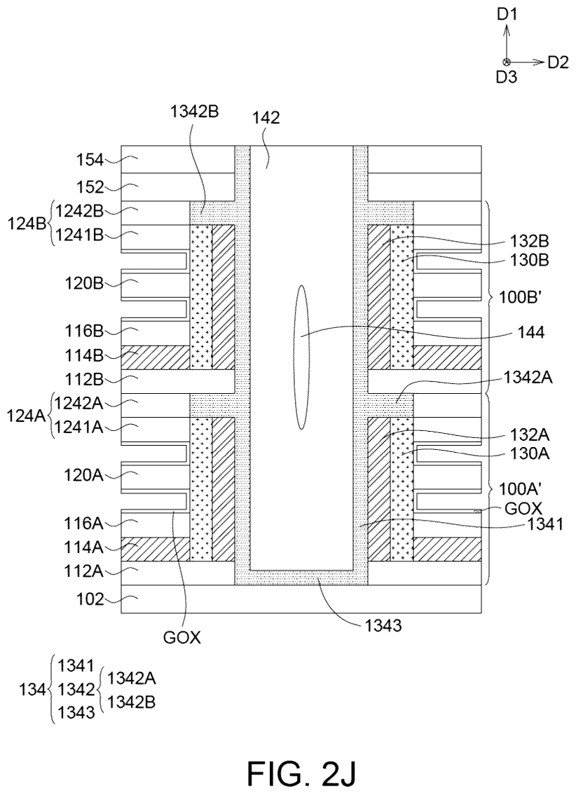

FIGS. 2A to 2J show a flow chart of a method for manufacturing the semiconductor device 10 shown in FIGS. 1A and 1B.

Referring to FIG. 2A, a bottom plate 102 and at least one stacked structure stacked on the bottom plate 102 along the first direction D1 are provided. In the present embodiment, the amount of at least one stacked structure is 2, that is, the at least one stacked structure includes a first stacked structure 100A′ and a second stacked structure 100B′ stacked on the first stacked structure 100A′. However, the present invention is not limited thereto. The amount of at least one stacked structure may be 1, 3, or more than 3.

The first stacked structure 100A′ includes a first insulating layer 112A, a first conductive layer 114A stacked on the first insulating layer 112A, and a plurality of insulating layers IL and a plurality of sacrificial layers SAL alternately stacked on the first conductive layer 114A. The insulating layers IL further include a second insulating layer 116A, a third insulating layer 120A, and a fourth insulating layer 124A. The sacrificial layers SAL include a first sacrificial layer 118A′ and a second sacrificial layer 122A′. That is, the first insulating layer 112A, the first conductive layer 114A, the second insulating layer 116A, the first sacrificial layer 118A′, the third insulating layer 120A, the second sacrificial layer 122A′ and the fourth insulating layer 124A are sequentially stacked on the bottom plate 102 along the first direction D1. Since the structures and materials of the first conductive layer 114A, the first insulating layer 112A, the second insulating layer 116A, the third insulating layer 120A and the fourth insulating layer 124A are all the same as those in the aforementioned embodiments of FIGS. 1A to 1B, the repeated parts will not be described in detail. The material of the sacrificial layers SAL is, for example, silicon nitride.

According to some embodiments, the material of the second insulating layer 116A, the third insulating layer 120A and the first insulating portion 1241A of the fourth insulating layer 124A may include a low-density oxide, such as low-density silicon oxide. Low-density silicon oxide can be formed by plasma enhanced chemical vapor deposition (PECVD). Due to low temperatures and specific process conditions, the resulting materials tend to have lower densities and may contain impurities or incomplete bonding. According to some embodiments, the material of the second insulating portion 1242A of the fourth insulating layer 124A may include a high-density oxide, such as high-density silicon oxide or tetraethoxysilane (TEOS) oxide. High-density silicon oxide is usually formed using methods such as high-density plasma chemical vapor deposition (HDP-CVD) or thermal oxidation. These methods produce a denser oxide layer with fewer voids and higher purity, making it more suitable for applications that require a high-quality insulating or protective layer. Additionally, different deposition temperatures can be used to form high-density silicon oxide and low-density silicon oxide. For example, low-density silicon oxide can be deposited at around 200° C., while high-density silicon oxide can be deposited at temperatures ranging from 400° C. to 600° C. The etch rate (dry or wet etch) of the lower density oxide is much faster than that of the higher density oxide.

According to some embodiments, the structure and material of the second stacked structure 100B′ may be identical to the structure and material of the first stacked structure 100A′. That is, the second stacked structure 100B′ may include a first insulating layer 112B, a first conductive layer 114B, a second insulating layer 116B, a first sacrificial layer 118B′, the third insulating layer 120B, the second sacrificial layer 122B′ and the fourth insulating layer 124B sequentially stacked on the first stacked structure 100A′ along the first direction D1. The fourth insulating layer 124B may include a first insulating portion 1241B and a second insulating portion 1242B. The materials and structures of the first insulating layer 112B, the first conductive layer 114B, the second insulating layer 116B, the first sacrificial layer 118B′, the third insulating layer 120B, the second sacrificial layer 122B′ and the first insulating portion 1241B and the second insulating portion 1242B of the fourth insulating layer 124B are respectively the same or similar to the materials and structures of the first insulating layer 112A, the first conductive layer 114A, the second insulating layer 116A, the first sacrificial layer 118A′, the third insulating layer 120A, the second sacrificial layer 122A′, the first insulating portion 1241A and the second insulating portion 1242A of the fourth insulating layer 124A. The repeated parts will not be described in detail.

Referring to FIG. 2B, an opening OP1 extending along the first direction D1 is formed on the structure shown in FIG. 2A. The opening OP1, for example, penetrates the insulating layers IL and the conductive layers CL of the first stacked structure 100A′ and the second stacked structure 100B′ along the first direction D1. The bottom of the opening OP1 exposes the bottom plate 102, for example. The opening OP1 is formed by, for example, an etching process.

Referring to FIG. 2C, first lateral holes HL1 extending along the second direction D2 is formed on the structure shown in FIG. 2B. The first lateral holes HL1 are in communication with and surround the opening OP1. For example, portions of the first conductive layers 114A and 114B are removed through an etching process (e.g., an etch-back process) to form the first lateral holes HL1.

Referring to FIG. 2D, second lateral holes HL2 extending along the second direction D2 is formed on the structure shown in FIG. 2C. The second lateral holes HL2 are in communication with and surround the opening OP1. For example, portions of the first sacrificial layers 118A′ and 118B′ and the second sacrificial layers 122A′ and 122B′ are removed through an etching process (such as an etch-back process) to form two second lateral holes HL2.

Referring to FIG. 2E, vertical holes HL3 extending along the first direction D1 is formed on the structure shown in FIG. 2D. The vertical holes HL3 are in communication with and surround the opening OP1. For example, portions of the first conductive layers 114A and 114B, the first sacrificial layers 118A′ and 118B′, the second insulating layers 116A and 116B, the second sacrificial layers 122A′ and 122B, the third insulating layers 120A and 120B, and the first insulating portions 1241A and 1241B of the fourth insulating layers 124A and 124B are removed through an etching process (such as a wet etching process) to form vertical holes HL3. The vertical holes HL3 are in communication with the opening OP1, the first lateral holes HL1 and the second lateral holes HL2.

Referring to FIG. 2F, channel layers 130A and 130B extending along the first direction D1 are formed on the structure shown in FIG. 2E. For example, the channel layers 130A and 130B are formed by filling the outside portions of the vertical holes HL3 with a channel material, such as polycrystalline silicon. In one embodiment, a channel material film conformal to the sidewalls and bottom of the opening OP1 and the vertical holes HL3 can be formed first, and then the excess channel material film is removed through an etching process (such as an etch-back process) to form the channel layers 130A and 130B.

Referring to FIG. 2G, dielectric layers 132A and 132B extending along the first direction D1 are formed on the structure shown in FIG. 2F. For example, the dielectric layers 132A and 132B adjacent to the channel layers 130A and 130B are formed by filling the inside portions of the vertical holes HL3 with a dielectric material, such as silicon nitride. In one embodiment, a dielectric material film conformal to the sidewalls and bottom of the opening OP1 and the vertical holes HL3 having the channel layers 130A and 130B can be first formed, and then the excess dielectric material film is removed through an etching process (such as an etch-back process) to form dielectric layers 132A and 132B.

Referring to FIG. 2H, lateral openings OP2 extending along the second direction D2 are formed on the structure shown in FIG. 2G. The lateral openings OP2 are in communication with and surround the opening OP1. For example, portions of the second insulating portions 1242A and 1242B are removed through an etching process (e.g., an etch-back process) to form the lateral openings OP2. The lateral openings OP2 can expose the upper surfaces of the dielectric layers 132A and 132B and the channel layers 130A and 130B.

Referring to FIG. 2I, the conductive connection structure 134 and the insulating pillar 142 are sequentially formed on the structure shown in FIG. 2H. For example, the conductive material can be filled in the lateral opening OP2 and on the sidewalls of the opening OP1 through a deposition process to form the conductive connection structure 134. The conductive material is, for example, a metal or other suitable conductive material. Then, the insulating material can be filled in the opening OP1 through a deposition process to form the insulating pillar 142. The insulating material is, for example, an oxide.

Referring to FIG. 2J, the sacrificial layers SAL (such as the first sacrificial layers 118A′ and 118B′ and the second sacrificial layers 122A′ and 122B′) can be removed through an etching process, and gate dielectric layers GOX are deposited in the recesses formed by the removed sacrificial layers SAL (such as the first sacrificial layers 118A′ and 118B′ and the second sacrificial layers 122A′ and 122B′). The material of the gate dielectric layers GOX may include an oxide material, for example Aluminum Oxide (AlO_{X}), Hafnium Oxide (HfO_{X}), Zirconium Oxide (ZrO_{X}) or other suitable material. Then, a conductive material is filled into the recesses formed by removing the sacrificial layers SAL to form second conductive layers 118A and 118B and third conductive layers 122A and 122B. The second conductive layers 118A and 118B and third conductive layers 122A and 122B are surrounded by gate dielectric layers GOX, respectively. In this way, the first stack 100A and the second stack 100B stacked on the bottom plate 102 along the first direction D1 are formed, and the semiconductor device 10 shown in FIGS. 1A and 1B is formed.

In summary, the present invention provides a semiconductor device and a method for manufacturing the same. Since the semiconductor device of the present invention has a stacking direction along the first direction (for example, vertically stacked), the stacking method is relatively easy and is beneficial to the development of miniaturized components. Therefore, compared with the traditional 1T 1C DRAM, the semiconductor device of the present invention can solve the scaling problem and provide a memory device with a higher storage capacity.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a bottom plate; and
at least one stack stacked on the bottom plate along a first direction, wherein the at least one stack comprises a first stack, and the first stack comprises:
a plurality of insulating layers and a plurality of conductive layers alternately stacked on the bottom plate along the first direction;
an insulating pillar extending along the first direction and penetrating the insulating layers and the conductive layers;
a conductive connection structure penetrating the insulating layers and the conductive layers and surrounding the insulating pillar;
a dielectric layer surrounding the conductive connection structure; and
a channel layer surrounding the dielectric layer and electrically connected to the conductive connection structure.

2. The semiconductor device according to claim 1, wherein the insulating layers comprise a first insulating layer, a second insulating layer, a third insulating layer and a fourth insulating layer, the conductive layers comprise a first conductive layer, a second conductive layer and a third conductive layer, the first insulating layer, the first conductive layer, the second insulating layer, the second conductive layer, the third insulating layer, the third conductive layer and the fourth insulating layer are sequentially stacked on the bottom plate along the first direction.

3. The semiconductor device according to claim 2, wherein a material of the first insulating layer, the second insulating layer, the third insulating layer and the fourth insulating layer comprises an oxide.

4. The semiconductor device according to claim 3, wherein the material of the first insulating layer is hafnium oxide or aluminum oxide.

5. The semiconductor device according to claim 3, wherein the fourth insulating layer comprises a first insulating portion and a second insulating portion, and the second insulating portion is stacked on the first insulating portion.

6. The semiconductor device according to claim 5, wherein a material of the second insulating layer, the third insulating layer and the first insulating portion of the fourth insulating layer comprises a low-density oxide; a material of the second insulating portion of the fourth insulating layer comprises a low-density oxide.

7. The semiconductor device according to claim 6, wherein a porosity of the low-density oxide is higher than a porosity of the high-density oxide.

8. The semiconductor device according to claim 1, wherein the conductive connection structure comprises a first connection portion and a second connection portion, and the second connection portion is connected to the first connection portion, and is in electrical contact with the channel layer; in a cross-sectional view, the first connection portion extends along the first direction, and the second connection portion extends along a second direction, and the second direction is different from the first direction..

9. The semiconductor device according to claim 1, wherein an amount of the at least one stack is plural, and the at least one stack further comprises a second stack, and the second stack is stacked on the first stack along the first direction.

10. The semiconductor device according to claim 1, wherein a structure of the second stack is identical to a structure of the first stack.

11. A method for manufacturing a semiconductor device, comprising:
providing a bottom plate; and
forming at least one stack stacked on the bottom plate along a first direction, wherein the at least one stack comprises a first stack, and the first stack comprises:
a plurality of insulating layers and a plurality of conductive layers alternately stacked on the bottom plate along the first direction;
an insulating pillar extending along the first direction and penetrating the insulating layers and the conductive layers;
a conductive connection structure penetrating the insulating layers and the conductive layers and surrounding the insulating pillar;
a dielectric layer surrounding the conductive connection structure; and
a channel layer surrounding the dielectric layer and electrically connected to the conductive connection structure.

12. The method according to claim 11, wherein the step for forming the first stack comprises:
forming a first stacked structure stacked on the bottom plate, wherein
the first stacked structure comprises a first insulating layer, a first conductive layer stacked on the first insulating layer, and a plurality of insulating layers and a plurality of sacrificial layers alternately stacked on the first conductive layer, the insulating layers comprises a second insulating layer, a third insulating layer and a fourth insulating layer, and the sacrificial layers comprises a first sacrificial layer and a second sacrificial layer, and
the first insulating layer, the first conductive layer, the second insulating layer, the first sacrificial layer, the third insulating layer, the second sacrificial layer and the fourth insulating layer are sequentially stacked on the bottom plate along the first direction.

13. The semiconductor device according to claim 12, wherein the fourth insulating layer comprises a first insulating portion and a second insulating portion, and the second insulating portion is stacked on the first insulating portion.

14. The semiconductor device according to claim 12, wherein the step for forming the first stack further comprises:
forming an opening extending along the first direction, the opening penetrating the first stacked structure;
removing a portion of the first conductive layer to form a first lateral hole;
removing a portion of the first sacrificial layer and the second sacrificial layer to form two second lateral holes;
removing a portion of the first conductive layer, the first sacrificial layer, the second insulating layer, the second sacrificial layer, the third insulating layer and the first insulating portion of the fourth insulating layer to form a vertical hole, wherein the vertical hole is in communication with the opening, the first lateral hole and the two second lateral holes;
forming the channel layer by filling a channel material in an outside portion of the vertical hole;
forming a dielectric layer adjacent to the channel layer by filling a dielectric material in an inside portion of the vertical hole;
removing a portion of the second insulating portion to form a lateral opening;
filling a conductive material in the lateral opening and sidewalls of the opening to form the conductive connection structure;
filling an insulating material in the opening to form the insulating pillar;
removing the sacrificial layers; and
filling a conductive material in recesses formed by removing the sacrificial layers to form the second conductive layer and the third conductive layer.

15. The method according to claim 12, wherein a material of the first insulating layer, the second insulating layer, the third insulating layer and the fourth insulating layer comprises an oxide.

16. The method according to claim 15, wherein the material of the first insulating layer is hafnium oxide or aluminum oxide.

17. The method according to claim 15, wherein the material of the second insulating layer, the third insulating layer and the first insulating portion of the fourth insulating layer comprises a low-density oxide; the material of the second insulating portion of the fourth insulating layer comprises a low-density oxide.

18. The method according to claim 11, wherein the conductive connection structure comprises a first connection portion and a second connection portion, and the second connection portion is connected to the first connection portion, and is in electrical contact with the channel layer; in a cross-sectional view, the first connection portion extends along the first direction, and the second connection portion extends along a second direction, and the second direction is different from the first direction..

19. The method according to claim 11, wherein an amount of the at least one stack is plural, and the at least one stack further comprises a second stack, and the second stack is stacked on the first stack along the first direction.

20. The method according to claim 19, wherein a structure of the second stack is identical to a structure of the first stack.
